(19) United States
(12) Patent Application Publication
(10) Pub. No.: US 2025/0351387 A1
(43) Pub. Date: Nov. 13, 2025

(54) DEEP TRENCH CAPACITOR AND METHODS OF FORMING THE SAME

(71) Applicant: Taiwan Semiconductor Manufacturing Company, Ltd., Hsin-Chu (TW)

(72) Inventors: Ting-Chen Hsu, Taichung City (TW); Ming-Hsun Lin, Hsinchu (TW); Jyun-Ying Lin, Yilan County (TW); Hsin-Li Cheng, Hsinchu (TW); Yingkit Felix Tsui, Cupertino, CA (US)

(21) Appl. No.: 18/658,786

(22) Filed: May 8, 2024

(51) Int. Cl. H01L 29/66; H01L 21/3065; H01L 21/308; H01L 27/08

(52) U.S. Cl. CPC H10D 1/047; H01L 21/3065; H01L 21/3086; H10D 84/212

(57) ABSTRACT

Semiconductor structures and methods are provided. An exemplary method according to the present disclosure includes forming a patterned hard mask over a semiconductor substrate, the patterned hard mask exposing a first portion of the semiconductor substrate and covering a second portion of the semiconductor substrate disposed adjacent to the first portion, wherein the second portion comprises an upper part in direct contact with the patterned hard mask and a lower part, performing a first etching process to recess the first portion and the lower part of the second portion to form a trench, performing a second etching process to trim the upper part of the second portion, after the performing of the second etching process, selectively removing the patterned hard mask, and forming a capacitor in and over the trench.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. For example, various methods have been developed to form capacitors. While existing capacitors are generally adequate in isolating active region segments, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of a method for fabricating a semiconductor structure, according to various aspects of the present disclosure.

FIGS. 2, 3, 4, 5, 6, 7, 8, 9, and 10 are fragmentary cross-sectional views of a workpiece during various fabrication stages in the method of FIG. 1, according to various aspects of the present disclosure.

FIGS. 11A, 11B, and 11C depict fragmentary cross-sectional views of a first alternative workpiece during various fabrication stages in the method of FIG. 1, according to various aspects of the present disclosure.

FIGS. 12A, 12B, and 12C depict fragmentary cross-sectional views of a second alternative workpiece during various fabrication stages in the method of FIG. 1, according to various aspects of the present disclosure.

FIGS. 13A and 13B depict fragmentary cross-sectional views of a third alternative workpiece during various fabrication stages in the method of FIG. 1, according to various aspects of the present disclosure.

FIGS. 14A, 14B, and 14C depict fragmentary cross-sectional views of a fourth alternative workpiece during various fabrication stages in the method of FIG. 1, according to various aspects of the present disclosure.

FIGS. 15A, 15B, and 15C depict fragmentary cross-sectional views of a fifth alternative workpiece during various fabrication stages in the method of FIG. 1, according to various aspects of the present disclosure.

FIG. 16 depicts a fragmentary cross-sectional view of a sixth alternative workpiece during various fabrication stages in the method of FIG. 1, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

Capacitors have been widely used in functional circuits such as mixed signal circuits, analog circuits, Radio Frequency (RF) circuits, Dynamic Random-Access Memories (DRAMs), embedded DRAMs, and logic operation circuits. In system-on-chip (SOC) applications, different capacitors for different functional circuits have to be integrated on a same chip to serve different purposes. For example, in mixed-signal circuits, capacitors are used as decoupling capacitors and high-frequency noise filters. For DRAM and embedded DRAM circuits, capacitors are used for memory storage, while for RF circuits, capacitors are used in oscillators and phase-shift networks for coupling and/or bypassing purposes. For microprocessors, capacitors are used for decoupling. A metal-insulator-metal (MIM) capacitor includes a sandwich structure of interleaving metal layers and insulator layers. An example MIM capacitor includes multiple conductor plates, each of which is insulated from an adjacent conductor plate by an insulator layer. In order to increase the capacitance of MIM capacitor or planar capacitor, deep trench capacitor (DTC) has been developed. However, as semiconductor devices continue to scale down, challenges arise in achieving desired performance. In an example process of forming deep trench capacitors, a patterned mask may be formed on the semiconductor substrate, while using the patterned mask as an etch mask, an etching process is performed to etch the semiconductor substrate to form deep trenches extending into the semiconductor substrate. Upon formation of the deep trenches, the portion of the semiconductor substrate disposed immediately adjacent to the deep trenches have sharp corners caused by shadow effect and ion scattering. Tip discharge may occur due to concentration of electric field lines at sharp corners of the portion of the semiconductor substrate. This discharge can lead to corona discharge, and device are susceptible to damage by electrical overstress (EOS).

The present disclosure provides methods of reducing tip discharge damage and semiconductor structures fabricated according to the methods. In an embodiment, after forming a patterned mask over a semiconductor substrate and after forming trenches in the semiconductor substrate using the patterned mask as an etch mask, a trimming process is performed to trim top sharp corners of the semiconductor substrate disposed immediately adjacent to the trenches. That is, an etching process is performed to turn sharp corners of the semiconductor substrate into rounded corners. In an embodiment, after forming the rounded corners, a thermal oxidization process is performed to the semiconductor substrate to form a dielectric liner. A capacitor is then formed over the dielectric liner and in and over the trenches. By trimming the semiconductor substrate to form rounded corners, deep trench capacitors formed in and over would have improved reliability.

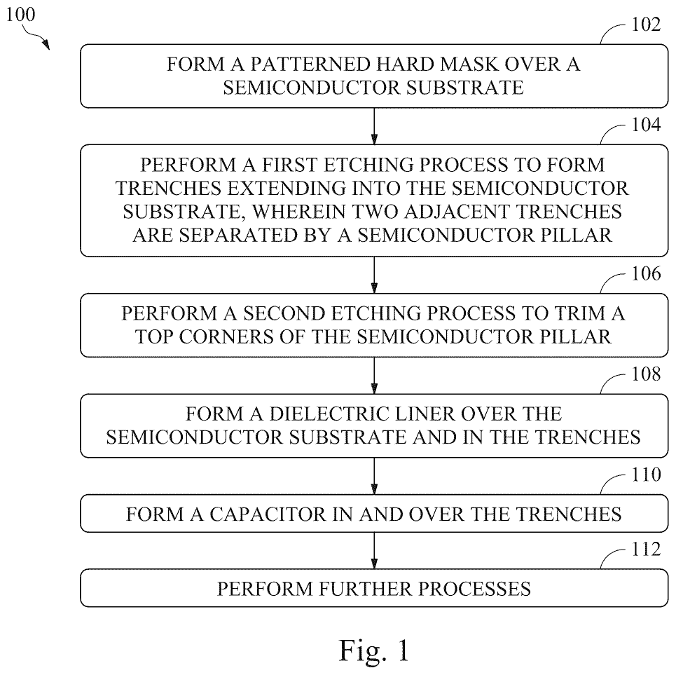

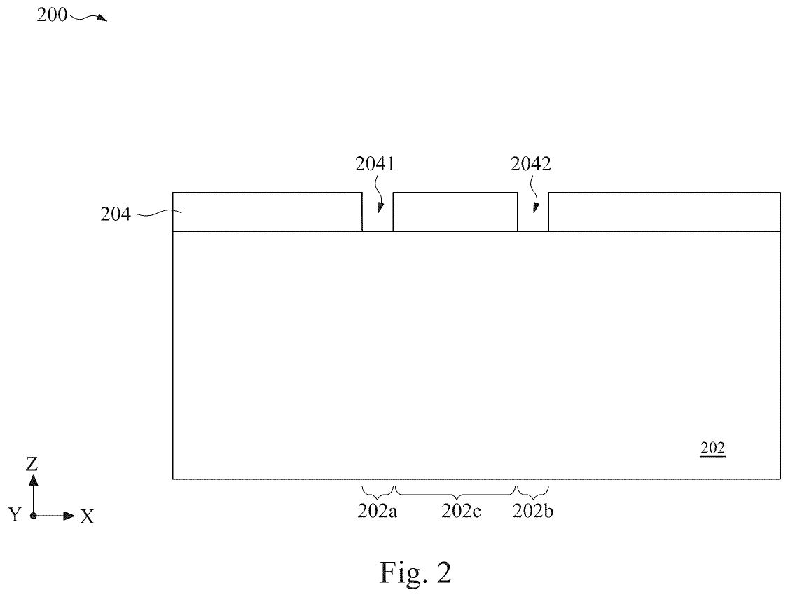

The various aspects of the present disclosure will now be described in more detail with reference to the figures. In that regard, FIG. 1 is a flowchart illustrating a method 100 for fabricating a semiconductor structure 200, according to embodiments of the present disclosure. Method 100 is described below in conjunction with FIGS. 2-16, which are fragmentary cross-sectional views of a workpiece at different stages of fabrication according to embodiments of method 100. Because the workpiece 200 will be fabricated into a semiconductor structure at the conclusion of the fabrication processes, the workpiece 200 may also be referred to as a semiconductor structure 200 as the context requires. Method 100 is merely an example and is not intended to limit the present disclosure to what is explicitly illustrated therein. Additional steps can be provided before, during, and after method 100, and some steps described can be replaced, eliminated, or moved around for additional embodiments of the method. Not all steps are described herein in detail for reasons of simplicity. Additionally, throughout the present application, like reference numerals denote like features, unless otherwise excepted.

Referring to FIGS. 1 and 2, method 100 includes a block 102 where a workpiece 200 is received. The workpiece 200 includes a substrate 202, which may be made of silicon or other semiconductor materials such as germanium. The substrate 202 also may include a compound semiconductor such as silicon carbide, gallium arsenic, indium arsenide, or indium phosphide. In some embodiments, the substrate 202 may include alloy semiconductor such as silicon germanium, silicon germanium carbide, gallium arsenic phosphide, or gallium indium phosphide. In an embodiment, the substrate 202 is made of silicon and may be referred to as a semiconductor substrate 202. In some embodiments, the substrate 202 may include an epitaxial layer, such as an epitaxial layer overlying a bulk semiconductor. In some embodiments, the substrate 202 may include one or more doped regions formed beneath an upper surface of the substrate 202. The doped region(s) may include an N-type doped region formed by implanting an N-type dopant into the substrate 202.

The workpiece 200 also includes a patterned hard mask 204 formed over the substrate 202. In an example process, a hard mask layer is formed over the substrate 202 by various suitable processes such as chemical vapor deposition (CVD), physical vapor deposition (PVD), atomic layer deposition (ALD). A lithography process is then performed. The lithography process can include forming a resist layer on the substrate 202 (for example, by spin coating), performing a pre-exposure baking process, performing an exposure process using a mask, performing a post-exposure baking process, and performing a developing process. During the exposure process, the resist layer is exposed to radiation energy (such as ultraviolet (UV) light, deep UV (DUV) light, or extreme UV (EUV) light), where the mask blocks, transmits, and/or reflects radiation to the resist layer depending on a mask pattern of the mask and/or mask type (for example, binary mask, phase shift mask, or EUV mask), such that an image is projected onto the resist layer that corresponds with the mask pattern. Since the resist layer is sensitive to radiation energy, exposed portions of the resist layer chemically change, and exposed (or non-exposed) portions of the resist layer are dissolved during the developing process depending on characteristics of the resist layer and characteristics of a developing solution used in the developing process. After development, the patterned resist layer includes a resist pattern that corresponds with the mask. While using the patterned resist layer as an etch mask, an etching process is performed to remove portions of the hard mask layer to form the patterned hard mask 204. This etching process selectively etches the hard mask layer without substantially etching the semiconductor substrate 202. In an embodiment, the patterned hard mask 204 includes oxide. In another embodiment, the patterned hard mask 204 includes nitride. In another embodiment, the patterned hard mask 204 is a multi-layer structure that includes a second layer formed over a first layer. The patterned resist layer is selectively removed after the forming of the patterned hard mask 204.

In this illustrated embodiment, the patterned hard mask 204 includes an opening 2041 exposing a portion 202a of the substrate 202 and an opening 2042 exposing a portion 202b of the substrate 202 and covers a portion 202c of the substrate 202. The portion 202c of the substrate 202 extends from the portion 202a of the substrate 202 to the portion 202b of the substrate 202. Although two openings 2041 and 2042 are illustrated, it is understood that the patterned hard mask 204 may include any suitable number of openings.

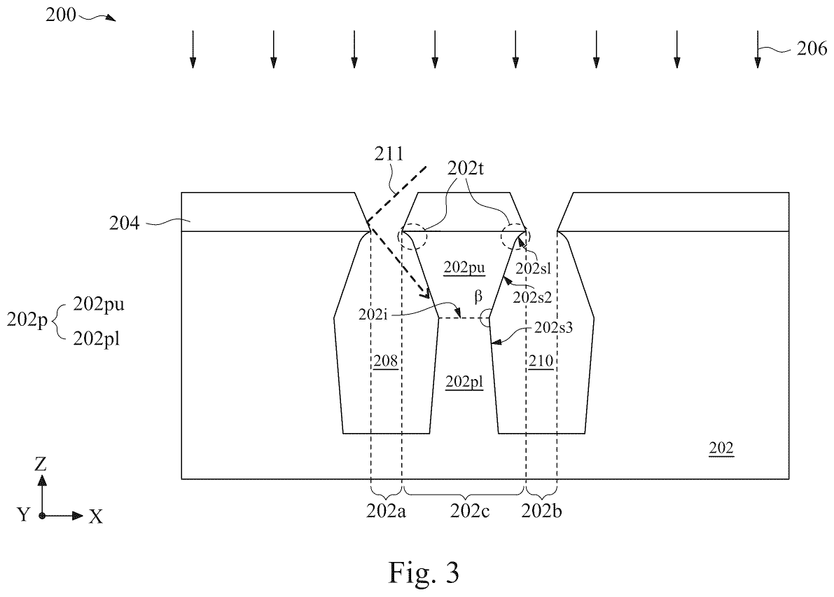

Referring to FIGS. 1 and 3, method 100 includes a block 104 where a first etching process 206 is performed to form trenches (e.g., trenches 208 and 210) extending into the semiconductor substrate 202. While using the patterned hard mask 204 as an etch mask, a first etching process 206 is performed to selectively etch the semiconductor substrate 202 to form a trench 208 and a trench 210. The first etching process 206 etches the semiconductor substrate 202 at a first etch rate and etches the patterned hard mask 204 at a second etch rate lower than the first etch rate. In an embodiment, a ratio of the first etch rate to the second etch rate is no less than 10. If the ratio is less than 10, to form a satisfactory deep trench for forming capacitors in desired regions, a thick hard mask layer will be needed. However, forming a thick hard mask layer would adversely increase the difficulty of patterning the thick hard mask layer.

In an embodiment, the first etching process 206 is a dry etching such as a plasma etching, a reactive ion etching, or a deep reactive ion etching. During the first etching process 206, a plasma contacting reactive species (e.g., fluorine-containing etchant) is used to etch the substrate 202. Ions in the plasma are accelerated towards the semiconductor substrate 202, removing material (e.g., silicon) of the semiconductor substrate 202 through a combination of chemical reactions and physical sputtering. During the first etching process 206, some ions are accelerated to vertically enter the semiconductor substrate 202 to form trenches within the portions 202a and 202b, while other ions may scatter when they meet surfaces of the patterned hard mask 204, as represented by the path 211. Those scattered ions may etch parts of the portion 202c of the semiconductor substrate 202 covered by the patterned hard mask 204. As a result, the trench 208 and the trench 210 each have a non-uniform width from bottom to top. The portion of the semiconductor substrate 202 disposed directly between the trench 208 and the trench 210 may be referred to as a semiconductor pillar 202p, or a silicon pillar 202p in embodiments where the semiconductor substrate 202 is formed of silicon. The semiconductor pillar 202p has a non-uniform width from bottom to top. More specifically, the semiconductor pillar 202p has a lower portion 202pl having a width gradually decreases along the Z direction and an upper portion 202pu having a width gradually increases along the Z direction. A virtual interface 202i between the upper portion 202pu and the lower portion 202pl is illustrated. As represented by FIG. 3, due to the mask shadow effect and ion scattering, the semiconductor pillar 202p has sharp top corners 202t.

In some embodiments, slope of a sidewall 202s1 of a top part of the upper portion 202pu is less than slope of a sidewall 202s2 of a bottom part of the upper portion 202pu. The sidewall 202s1 and the top surface of the semiconductor pillar 202p forms an acute angle. In this embodiment, a top surface of the top part of the upper portion 202pu is in direct contact with and aligns with the patterned hard mask 204 thereon, and the patterned hard mask 204 overhangs remaining portions of the semiconductor pillar 202p. The sidewall 202s2 and a sidewall 202s3 of the lower portion 202pl of the semiconductor pillar 202p forms an obtuse angle β that is greater than 180°.

Referring to FIGS. 1 and 4-5, method 100 includes a block 106 where a second etching process 212 is performed to etch the patterned hard mask 204 and trim the upper portion 202pu of the semiconductor pillar 202p. As described above, tip (e.g., sharp top corners 202t) of the semiconductor pillar 202p is prone to discharge. The phenomenon of tip discharge may cause serious leakage current for capacitors formed over and adjacent to the semiconductor pillar 202p. In the present embodiments, after the performing of the first etching process 206, the second etching process 212 is performed to trim the upper portion 202pu of the semiconductor pillar 202p. The patterned hard mask 204 and the upper portion 202pu of the silicon pillar 202p before the performing of the second etching process 212 are represented by dashed lines. The patterned hard mask 204, the top corners 202t, and the upper portion 202pu after the performing of the second etching process 212 are referred to as patterned hard mask 204′, top corners 202t′, and the upper portion 202pu′, respectively. The second etching process 212 etches the upper portion 202pu of the semiconductor pillar 202p at a third etch rate and etches the patterned hard mask 204 at a fourth etch rate lower than the third etch rate. In an embodiment, the fourth etch rate is higher than the second etch rate. In an embodiment, a ratio of the third etch rate to the fourth etch rate is greater than 5 such that the second etching process 212 may trim the sharp top corners 202t of the silicon pillar 202p without fully removing the patterned hard mask 204. The ratio of the third etch rate to the fourth etch rate is less than the ratio of the first etch rate to the second etch rate.

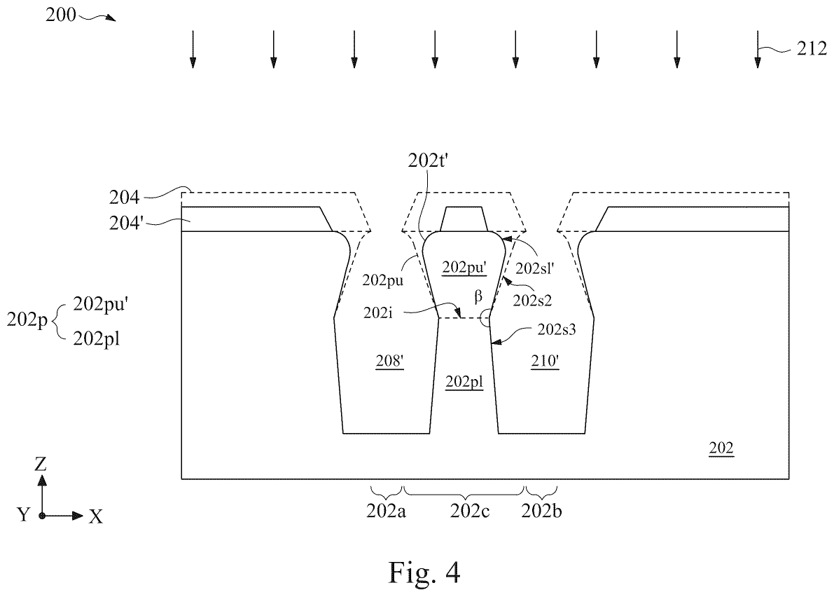

As illustrated by FIG. 4, the performing of the second etching process 212 reduces the dimensions (e.g., both width and thickness) of the patterned hard mask 204 and trims the sharp top corners 202t of the silicon pillar 202p, thereby forming rounded top corners 202t′ without substantially etching the lower portion 202pl of the silicon pillar 202p. In an embodiment, the second etching process 212 is a dry etching such as a plasma etching, a reactive ion etching, or a deep reactive ion etching. In the present embodiments, high molecular weight etchant (e.g., argon) is employed to increase physical ion bombardment ability. For example, the performing of the second etching process 212 includes implementing a combination of CF₄ and Argon. In an embodiment, a ratio of a flow rate of CF₄ and a flow rate of argon (Ar) is in a range between about 0.85 and 1.15. To trim the sharp top corners 202t of the silicon pillar 202p without substantially etching the lower portion 202pl of the silicon pillar 202p, a process pressure of the second etching process is set to be lower than 20 millitorr (mTorr). As represented by FIG. 4, the upper portion 202pu′ of the silicon pillar 202p has rounded top corners 202t′. Sidewall 202s1′ of the top part of the upper portion 202pu′ of the silicon pillar 202p curves outward. That is, after forming the rounded top corners 202t′, the upper portion 202pu′ of the silicon pillar 202p has a non-uniform width from bottom to top. More specifically, the width of the upper portion 202pu′ of the silicon pillar 202p gradually increases and then gradually decreases along the Z direction. In other words, the widest part of the upper portion 202pu′ is between the interface 202i (e.g., bottommost surface of the upper portion 202pu′) and the topmost surface of the upper portion 202pu′. In an embodiment, the sidewall 202s1′ is not covered by the patterned hard mask 204.

After the performing of the second etching process 212, a third etching process 213 is performed to selectively remove the patterned hard mask 204′ without substantially etching the substrate 202, including the silicon pillar 202p. The third etching process 213 etches the patterned hard mask 204′ at a fifth etch rate and etches the substrate 202 at a sixth etch rate lower than the fifth etch rate. The silicon pillar 202p includes the lower portion 202pl having a non-uniform width that gradually reduces from width W1 to width W2 along the Z direction. The silicon pillar 202p also includes the upper portion 202pu′ having a non-uniform width that gradually increases from width W2 to width W3 and gradually decreases from width W3 to width W4 along the Z direction.

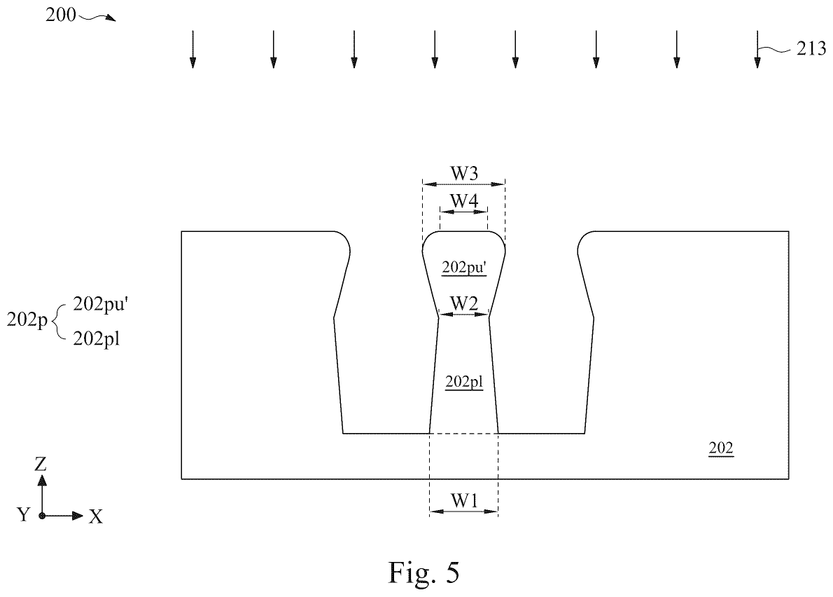

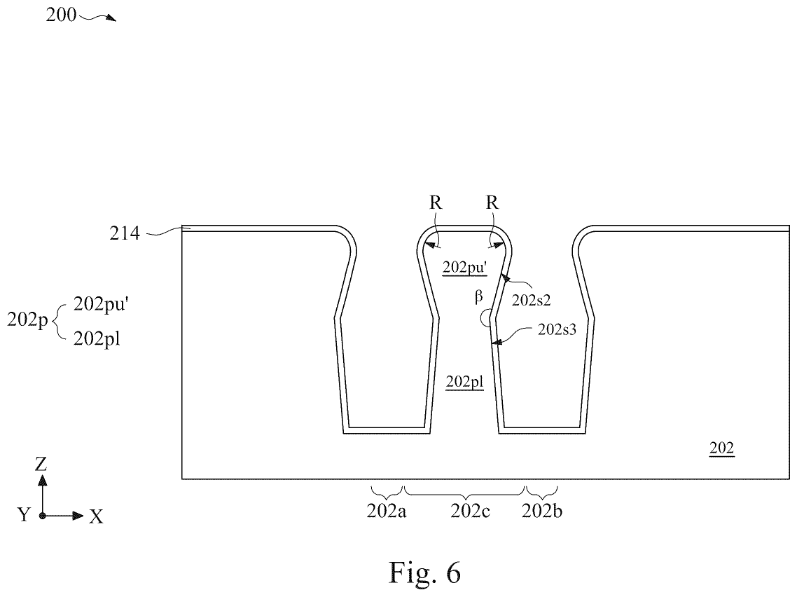

Referring to FIGS. 1 and 6, method 100 includes a block 108 where a dielectric liner 214 is formed over the substrate 202. The dielectric liner 214 is conformally formed on the substrate 202, including on an inner surface of the trenches 208 and 210 and an upper surface of the substrate 202. The dielectric liner 214 may be made of thermally grown material including silicon oxide or silicon nitride. The dielectric liner 214 may be deposited by chemical vapor deposition (CVD), such as plasma enhanced CVD (PECVD), low pressure CVD (LPCVD) or atmosphere pressure CVD (APCVD). In one embodiment, the dielectric liner 214 is formed by a thermal oxidation process and covers an entire top surface of the substrate 202, including in the trenches 208 and 210. In embodiments where the dielectric liner 214 is formed by a thermal oxidation process (e.g., CVD or ALD), the dielectric liner 214 may have a non-uniform thickness. In embodiments where the dielectric liner 214 is formed by a deposition process (e.g., CVD or ALD), the dielectric liner 214 may have a substantially uniform thickness. In an embodiment, the dielectric liner 214 is formed by a thermal oxidation process and includes silicon oxide, and after forming the dielectric liner, the corner of the silicon pillar has a radius of curvature R. A ratio of the radius of curvature R of the top corner 202t′ to the width W1 (shown in FIG. 5) is no less than 0.07. If the ratio is less than 0.07, the corners 202t′ are not smooth enough to release tip discharge.

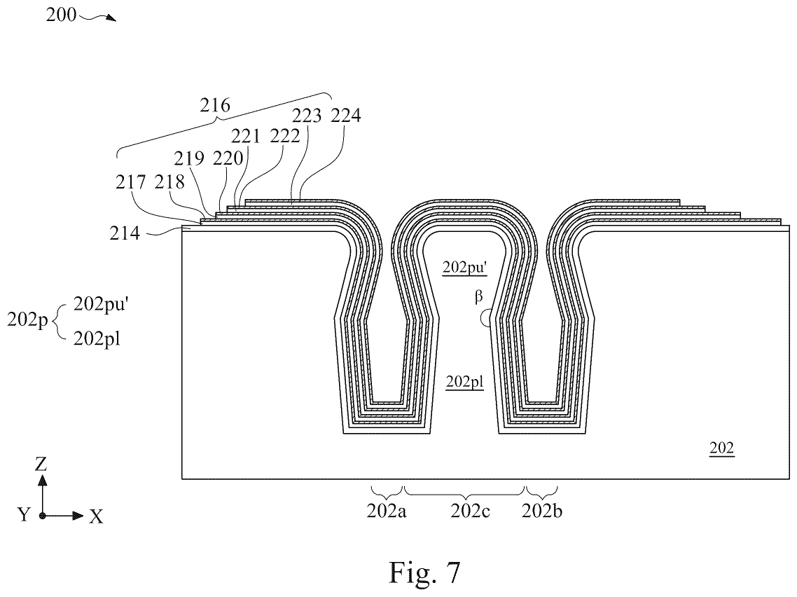

Referring to FIGS. 1 and 7, method 100 includes a block 110 where a capacitor 216 is formed in and over the trenches 208 and 210. The forming of the capacitor 216 includes performing a combination of deposition, lithography and etching processes. In an example process, a first conductive layer 217 is conformally deposited over the substrate 202 and in the trenches 208 and 210. The first conductive layer 217 may be deposited over the substrate 202 using ALD, physical vapor deposition (PVD), CVD, or other suitable deposition processes. In some embodiments, the first conductive layer 217 may include titanium (Ti), tantalum (Ta), titanium nitride (TiN), tantalum nitride (TaN), copper (Cu), cobalt (Co), nickel (Ni), tungsten (W), aluminum (Al), or other suitable materials. Then, a first dielectric layer 218 is formed on the first conductive layer 217 using CVD, ALD, or a suitable deposition method and may be a high-k dielectric layer that includes hafnium oxide, aluminum oxide, zirconium oxide, titanium oxide, tantalum oxide, or a combination thereof. The first conductive layer 217 and the first dielectric layer 218 are then patterned to form a first conductor plate 217 and a first insulator layer 218, respectively. In an embodiment, a sidewall of the first insulator layer 218 aligns with a sidewall of the first conductor plate 217. Additional layer such as a second conductor plate 219, a second insulator layer 220, a third conductor plate 221, a third insulator layer 222, a fourth conductor plate 223, and a fourth insulator layer 224 are sequentially formed over the first insulator layer 218 to finish the fabrication of the trench capacitor 216 in the trenches 208 and 210 and over the substrate 202. The fabrication processes and compositions of the second, third and fourth insulator layers 220, 222, and 224 may be similar to those of the first insulator layer 218. The fabrication processes and compositions of the second, third and fourth conductor plates and 219, 221, 223 may be similar to those of the first conductor plate 217. It is understood that the number of conductor plates and insulator layers of the capacitor 216 depicted in FIG. 7 is just an example, and the capacitor 216 may include any suitable number of conductor plates, and adjacent conductor plates are insulated from one another by an insulator layer.

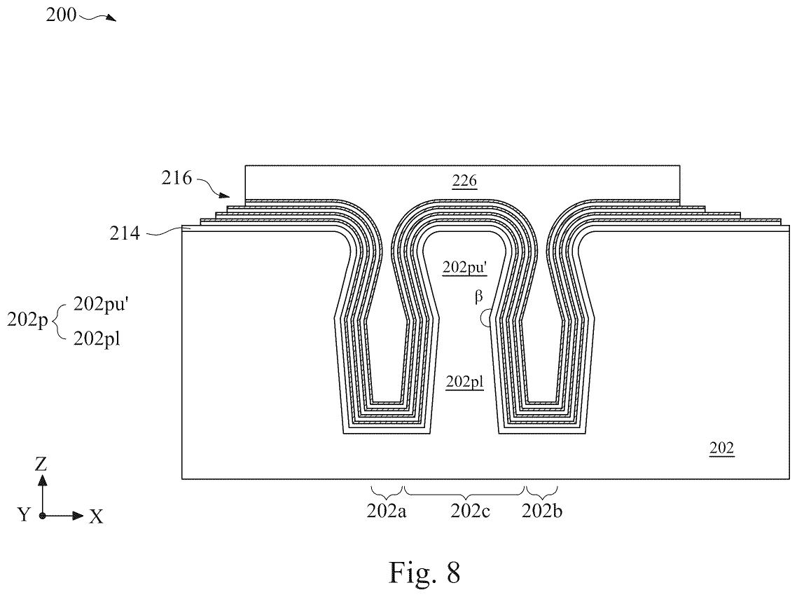

Referring to FIGS. 1 and 8-10, method 100 includes a block 112 where further processes are performed to finish the fabrication of the semiconductor structure 200. Such further processes may include, for example, as illustrated in FIG. 8, after the formation of the capacitor 216, forming a dielectric layer 226 to fill remaining portions of the trenches 208 and 210. The dielectric layer 226 may be deposited using a suitable deposition technique, such as ALD, PVD or CVD. The dielectric layer 226 may include an oxide such as silicon oxide, a nitride such as a silicon nitride, a combination thereof, a multilayer thereof, or the like. In an embodiment, the dielectric layer 226 includes silicon oxide. A planarization process (e.g., chemical mechanical polishing (CMP)) may be performed after the deposition of the dielectric layer. In some embodiments, after the planarization process, the dielectric layer 226 may be patterned to remove portions of the dielectric layer 226 extending beyond the topmost layer of the capacitor 216. In some other embodiments, after the planarization process, the dielectric layer 226, a conductive layer for forming the topmost conductor plate (e.g., the fourth conductor plate 223) and a dielectric layer for forming the topmost insulator layer (e.g., the fourth insulator layer 224) are patterned a common process such that a sidewall of the dielectric layer 226 aligns with sidewalls of the topmost conductor plate 223 and the topmost insulator layer 224.

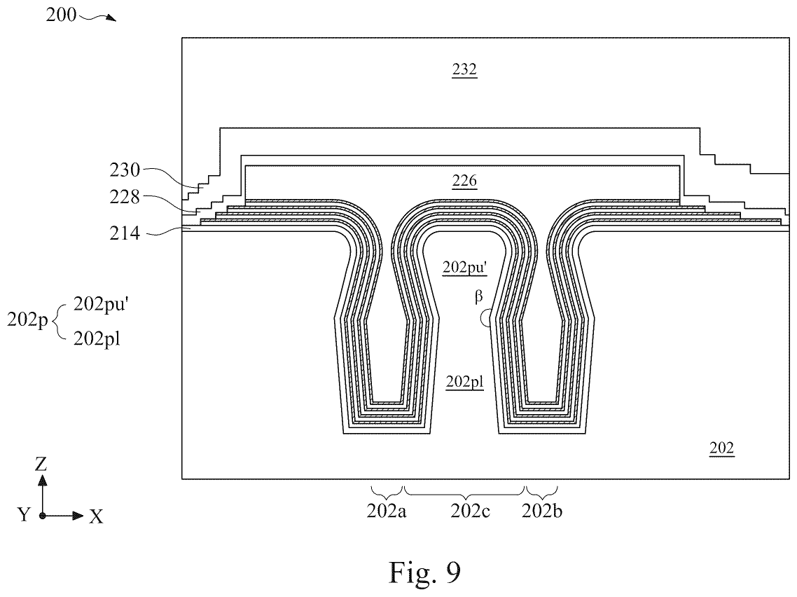

After forming and patterning the dielectric layer 226, as illustrated in FIG. 9, a dielectric material layer 228 may be conformally formed over the workpiece 200. Any suitable deposition process may be used, including CVD, PVD, ALD, or combinations thereof. In some embodiments, the dielectric material layer 228 includes undoped silicon oxide or undoped silicate glass (USG). In an embodiment, after forming the dielectric material layer 228, an etch stop layer (ESL) 230 is formed over the substrate 202. The ESL 230 may include one or more layers of dielectric materials. Suitable dielectric materials may include oxides (such as silicon oxide, aluminum oxide, or the like), nitrides (such as SiN, or the like), oxynitrides (such as SiON, or the like), oxycarbides (such as SiOC, or the like), carbonitrides (such as SiCN, or the like), carbides (such as SiC, or the like), combinations thereof, or the like, and may be formed using spin-on coating, CVD, plasma-enhanced CVD (PECVD), ALD, a combination thereof, or the like. The ESL 230 is configured to aid in forming contact vias that provide electrical connection to the conductor plates (e.g., conductor plates 217, 219, 221, 223) of the trench capacitor 216.

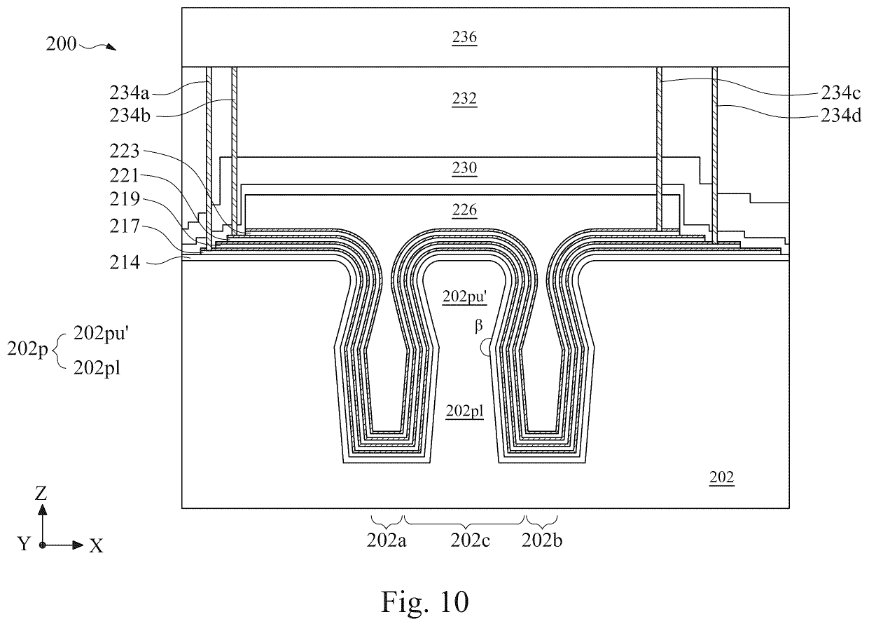

Still referring to FIGS. 9-10, after the formation of the ESL 230, an interlayer dielectric layer 232 is formed over the substrate 202. The interlayer dielectric layer 232 may include a low-k dielectric material such as phosphosilicate glass (PSG), borophosphosilicate glass (BPSG), fluorosilicate glass (FSG), silicon oxycarbide, silicon carbon material, compounds thereof, composites thereof, combinations thereof, or the like, and may be formed by any suitable method, such as spin-on coating, CVD, PECVD, ALD, a combination thereof, or the like. Contact vias (such as contact vias 234a, 234b, 234c, 234d) may be then formed using any suitable methods. In some embodiments, the steps for forming the contact vias include forming a patterned mask film, forming openings in the respective dielectric layers (e.g., 232, 230, 228), depositing one or more barrier/adhesion layers (not shown) in the openings, and filling the openings with a conductive material. A chemical mechanical polishing (CMP) is then performed to remove excess materials of the one or more barrier/adhesion layers and the conductive material overfilling the openings. The barrier layer may include titanium nitride (TiN), tantalum nitride (TaN), or another metal nitride. The conductive material filling layer may be formed of copper (Cu), aluminum (Al), or an alloy thereof. In the illustrated embodiment, the contact via 234a is electrically coupled to and in direct contact with the first conductor plate 217, the contact via 234b is electrically coupled to and in direct contact with the second conductor plate 219, the contact via 234c is electrically coupled to and in direct contact with the third conductor plate 221, and the contact via 234d is electrically coupled to and in direct contact with the fourth conductor plate 223. After forming the contact vias 234a-234d, further processes may be performed. Such further processes may include, for example, forming a dielectric layer on the contact vias 234a-234d, patterning the dielectric layer to form a number of openings exposing the contact vias 234a, 234b, 234c, and forming metal lines in the openings. In some embodiments, the metal lines may be part of a redistribution layer (RDL) to reroute bond connections between upper and lower layers. Such further processes may also include formation of a passivation structure over the metal lines, formation of openings through the third passivation structure to expose the metal lines, deposition of one or more polymeric material layers, patterning of the one or more polymeric material layers, deposition of an under-bump-metallurgy (or under-bump-metallization (UBM)) layer, deposition of a copper-containing bump layer, deposition of a cap layer, deposition of a solder layer, and reflowing of the solder layer. These further processes form contact structures for connection to external circuitry.

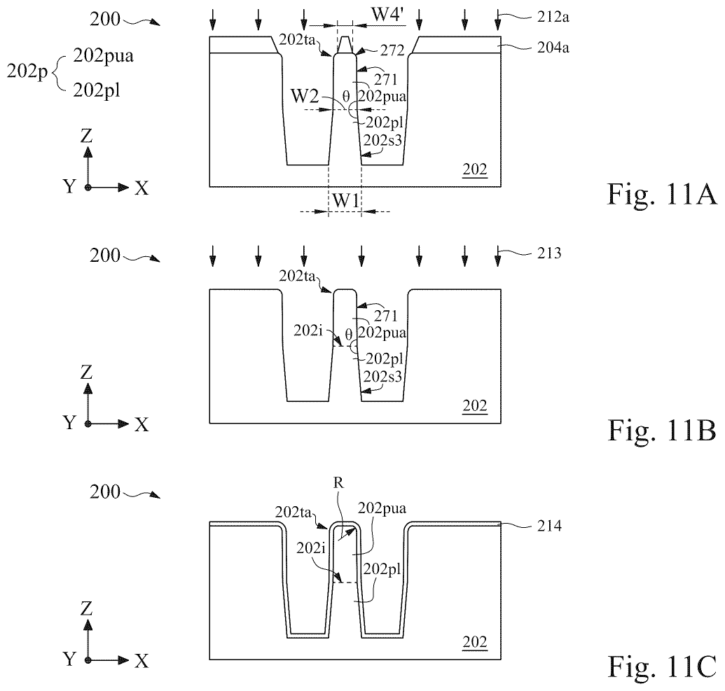

In the above embodiments, the profile of the upper portion 202pu′ of the silicon pillar 202p resembles an inverted trapezoid with rounded top corners 202t′. The upper portion 202pu′ of the silicon pillar 202p may have other profiles. FIGS. 11A-11C depict fragmentary cross-sectional views of a first alternative workpiece, during various stages of operations in the method of FIG. 1, according to various aspects of the present disclosure. In this alternative embodiment, after performing operations in blocks 102 and 104 of method 100, an etching process 212a is performed to etch the patterned hard mask 204 and trim the top corners 202t of the silicon pillar 202p. The etching process 212a is substantially same to the second etching process 212 (described with reference to FIG. 4) in terms of etchants. One difference between the etching process 212a and the second etching process 212 is that the etching process 212a is performed for a longer duration than the second etching process 212. As a result of the performing of the etching process 212a, compared with the embodiment described with reference to FIG. 4, a thickness and width of the patterned hard mask 204 is further reduced, and a width of the upper portion 202pu of the silicon pillar 202p also decreases. The patterned hard mask 204 after the performing of the etching process 212a is referred to as the patterned hard mask 204a, and the upper portion 202pu of the silicon pillar 202p after the performing of the etching process 212a is referred to as the upper portion 202pua. In this embodiment, the upper portion 202pua resembles a rounded rectangle and has a non-uniform width. More specifically, a lower part of the upper portion 202pua has a uniform width that is substantially equal to the width W2, and an upper part of the upper portion 202pua has a non-uniform width that gradually reduces from the width W2 to a width W4′. W4′ is less than W4 (shown in FIG. 5). In an embodiment, a sidewall 271 of the lower part of the upper portion 202pua is substantially vertical and a sidewall 272 of the upper part of the upper portion 202pua curves outward. An angle θ (shown in FIGS. 11A-11B) between the sidewall 271 and the sidewall 202s3 of the lower portion 202pl is greater than 180°. The upper portion 202pua of the silicon pillar 202p has rounded top corners 202ta. In an embodiment, a ratio of the radius of curvature R of the top corner 202ta to the width W1 is no less than 0.07. If the ratio is less than 0.07, the corners 202t′ are not smooth enough to release tip discharge. In an embodiment, the radius of curvature R of the top corner 202ta is greater than 10 nm such that the top corner 202ta is smooth enough to reduce or avoid tip discharge. After performing the etching process 212a, as represented by FIGS. 11B-11C and described above with reference to FIG. 1, the patterned hard mask 204a is selectively removed, and the dielectric liner 214 is then formed. Operations in blocks 110-112 may be then performed to finish the fabrication of the semiconductor structure 200.

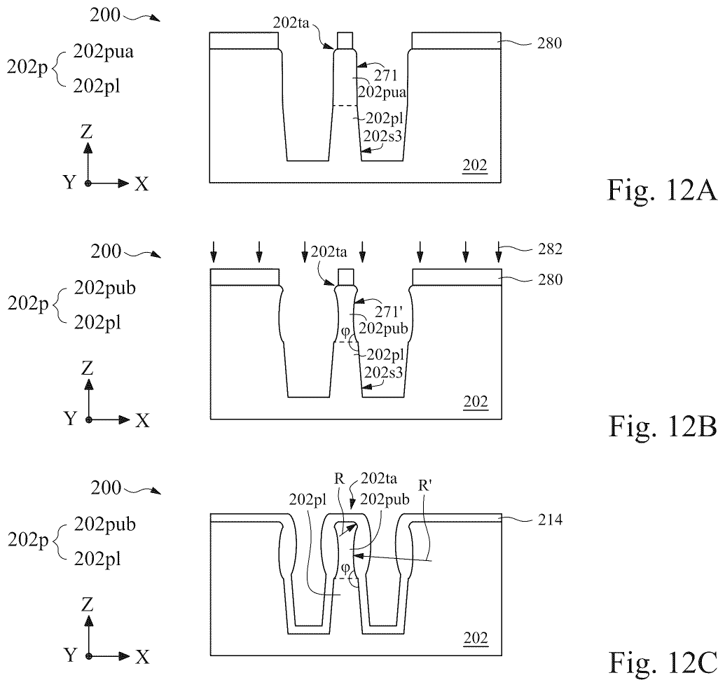

FIGS. 12A-12C depict fragmentary cross-sectional views of a second alternative workpiece, during various stages of operations in the method of FIG. 1, according to various aspects of the present disclosure. In this second alternative embodiment, compared to the first alternative embodiment described with reference to FIGS. 11A-11C, the upper portion 202pua of the silicon pillar 202p is further trimmed to form another profile and enlarge the trenches 208 and 210. In this second alternative embodiment, the patterned hard mask 204a (shown in FIG. 11A) includes a first layer 280 (shown in FIG. 12A) and a second layer (not separately labeled) formed over the first layer 280. The first layer 280 and the second layer have different material compositions. After performing the etching process 212a described above with reference to FIG. 11A, a planarization process or an etching process is performed to remove the second layer of the patterned hard mask 204a, leaving the first layer 280 on the substrate 202, as shown in FIG. 12A. Then, with reference to FIG. 12B, an etching process 282 is performed to selectively trim the upper portion 202pua of the silicon pillar 202p without substantially etching the first layer 280 and the lower portion 202pl of the silicon pillar 202p. In this embodiment, after the performing of the etching process 282, the sidewall 271 curves inward. The sidewall 271 after the performing of the etching process 282 may be referred to as the sidewall 271′, and the upper portion 202pua after the performing of the etching process 282 may be referred to as the upper portion 202pub. The angle φ between the upper portion 202pub and the lower portion 202pl of the silicon pillar 202p is greater than 90° and less than 180°. In this embodiment, the upper portion 202pub resembles a diverging lens with rounded top corners. A ratio of the radius of curvature R of the top corner 202ta to the width W1 is no less than 0.07. If the ratio is less than 0.07, the corners 202t′ may be not smooth enough to release tip discharge. In an embodiment, the radius of curvature R of the top corner 202ta is greater than 10 nm, and a radium of curvature R′ of the sidewall 271′ is in a range between about 80 nm and about 500 nm. After performing the etching process 212b, with reference to FIG. 12C and FIG. 1, the first layer 280 of the patterned hard mask 204a is selectively removed, and the dielectric liner 214 is then formed. In this embodiment, the dielectric liner 214 has a non-uniform thickness. For example, the portion of the dielectric liner 214 extending along the sidewall 271′ of the upper portion 202pub may be thicker than the portion of the dielectric liner 214 extending along a sidewall of the lower portion 202pl of the silicon pillar 202p. Operations in blocks 110-112 may be then performed to finish the fabrication of the semiconductor structure 200.

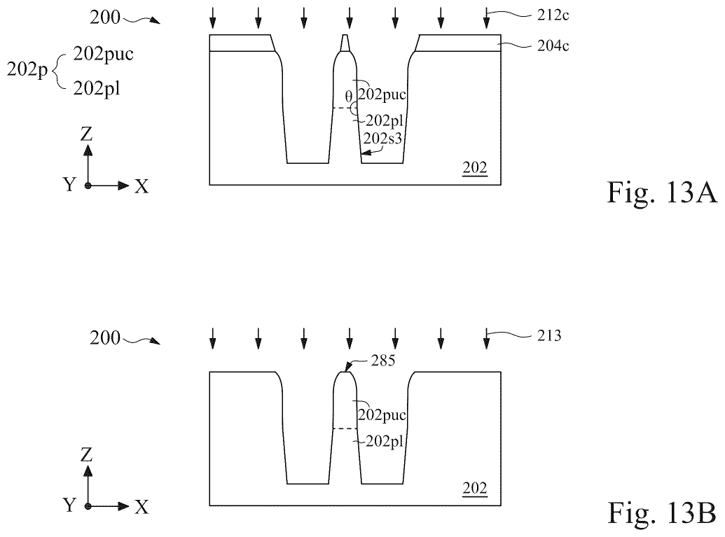

FIGS. 13A-13B depict fragmentary cross-sectional views of a third alternative workpiece, during various stages of operations in the method of FIG. 1, according to various aspects of the present disclosure. In this third alternative embodiment, after performing operations in blocks 102 and 104 of method 100, an etching process 212c is performed to etch the patterned hard mask 204 and trim the top corners 202t of the silicon pillar 202p. The etching process 212c is substantially same to the second etching process 212 (described with reference to FIG. 4) in terms of etchants. One difference between the etching process 212c and the second etching process 212 is that the etching process 212c is performed for a longer duration than the second etching process 212. In an embodiment, the etching process 212c is performed for a longer duration than the etching process 212a described with reference to FIGS. 11A-11C. As a result of the performing of the etching process 212c, compared with the embodiments described with reference to FIG. 4 and FIGS. 11A-11C, a thickness and a width of the patterned hard mask 204a (shown in FIG. 11A) is further reduced, and a width of the upper portion 202pua (shown in FIGS. 11A-11C) of the silicon pillar 202p also decreases. The patterned hard mask 204 after the performing of the etching process 212c is referred to as the patterned hard mask 204c, and the upper portion 202pu of the silicon pillar 202p after the performing of the etching process 212c is referred to as the upper portion 202puc. In this embodiment, after the performing of the etching process 212c, the upper portion 202puc resembles a bullet with a flat top surface 285. In an embodiment, the radius of curvature of the top corner of the upper portion 202puc of the silicon pillar 202p is greater than 10 nm such that the top corner is smooth enough to alleviate tip discharge effect. After performing the etching process 212c, as represented by FIG. 13B and described above with reference to FIG. 1, the patterned hard mask 204c is selectively removed. Operations in blocks 108-112 may be then performed to finish the fabrication of the semiconductor structure 200.

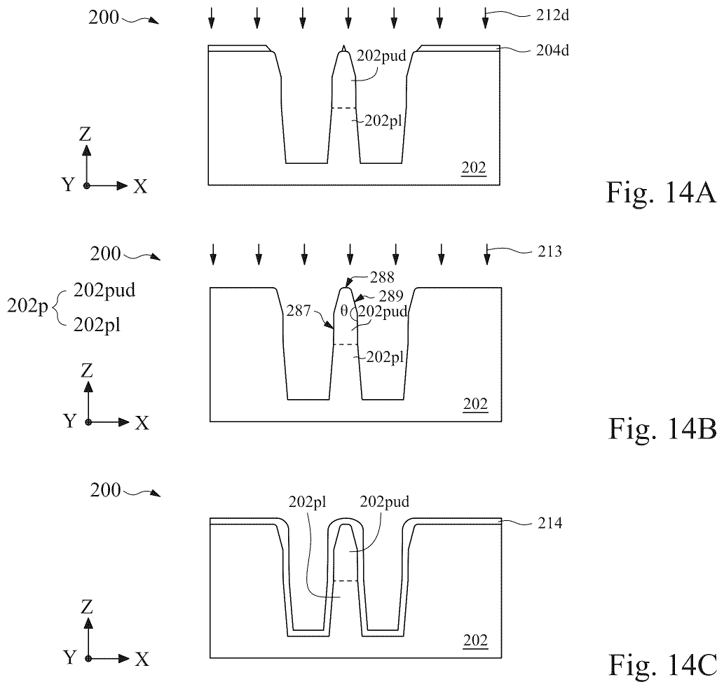

FIGS. 14A-14C depict fragmentary cross-sectional views of a fourth alternative workpiece, during various stages of operations in the method of FIG. 1, according to various aspects of the present disclosure. In this fourth alternative embodiment, after performing operations in blocks 102 and 104 of method 100, an etching process 212d is performed to etch the patterned hard mask 204′ and trim the top corners 202t of the silicon pillar 202p. The etching process 212d is substantially same to the second etching process 212 (described with reference to FIG. 4) in terms of etchants. One difference between the etching process 212d and the second etching process 212 is that the etching process 212d is performed for a longer duration than the second etching process 212. In an embodiment, the etching process 212d is performed for a longer duration than the etching process 212c described with reference to FIGS. 13A-13B. As a result of the performing of the etching process 212d, compared with the embodiments described with reference to FIG. 4 and FIGS. 11A-11C and FIGS. 13A-13B, a thickness and width of the patterned hard mask 204c is further reduced, and a width of the upper portion 202puc of the silicon pillar 202p also decreases. For example, the portion of the patterned hard mask 204 disposed directly over the silicon pillar 202p is almost fully removed. The patterned hard mask 204 after the performing of the etching process 212d is referred to as the patterned hard mask 204d, and the upper portion 202pu of the silicon pillar 202p after the performing of the etching process 212d is referred to as the upper portion 202pud. The profile of the upper portion 202pud is similar to the profile of the upper portion 202puc, and one of the differences includes that a top surface 288 of the upper portion 202pud is a convex top surface that curves outward. The upper portion 202pud also includes a vertical sidewall 287 and a tilted sidewall 289 extending from the vertical sidewall 287 to the convex top surface 288. In this embodiment, after the performing of the etching process 212d, the upper portion 202pud resembles a bullet with a curved top surface. The radius of curvature of the top corner of the upper portion 202pud of the silicon pillar 202p is greater than 10 nm such that the top corner is smooth enough to alleviate tip discharge effect. The tilted sidewall 289 and the vertical sidewall 287 forms an angle that is greater than 90° and less than 180°. After performing the etching process 212d, as represented by FIGS. 14B-14C and described above with reference to FIG. 1, the patterned hard mask 204d is selectively removed, and the dielectric liner 214 is then formed. In this embodiment, the dielectric liner 214 has a non-uniform thickness. For example, the portion of the dielectric liner 214 extending along the sidewall 289 may be non- uniform and is thicker than other portions of the dielectric liner 214. Operations in blocks 110-112 may be then performed to finish the fabrication of the semiconductor structure 200.

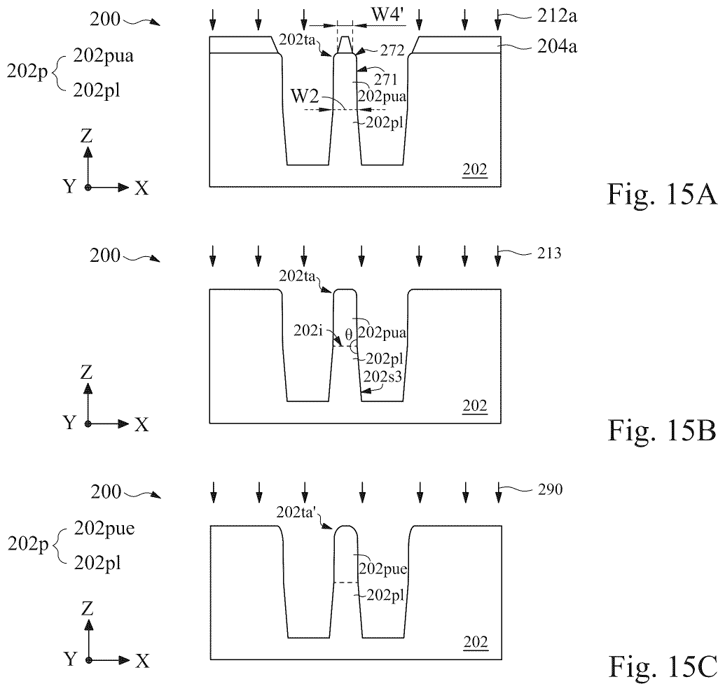

FIGS. 15A-15C depict fragmentary cross-sectional views of a fifth alternative workpiece, during various stages of operations in the method of FIG. 1, according to various aspects of the present disclosure. In this fifth alternative embodiment, after performing operations in blocks 102 and 104 of method 100, the etching process 212a (described with reference to FIG. 11A) is first performed to etch the patterned hard mask and trim the top corners 202t of the silicon pillar 202p. The workpiece 200 illustrated in FIG. 15A and the workpiece 200 illustrated in FIG. 11A are substantially the same. After performing the etching process 212a, as described above with reference to FIGS. 5 and 11B and illustrated in FIG. 15B, the third etching process 213 is performed to selectively remove the patterned hard mask 204a. In this fifth alternative embodiment, after the removing of the patterned hard mask 204a, with reference to FIG. 15C, a fourth etching process 290 is performed to further trim the substrate 202, including the upper portion 202pua of the silicon pillar 202p. In an embodiment, the fourth etching process 290 is substantially same to the second etching process 212 and the etching process 212a in terms of etchant(s). The extent at which the substrate 202 is further trimmed is controlled by the duration of the fourth etching process 290. In an embodiment, the performing of the fourth etching process 290 would not substantially etch the lower portion 202pl of the silicon pillar 202p. The upper portion 202pua of the silicon pillar 202p after the performing of the fourth etching process 290 may be referred to as the upper portion 202pue. As represented by FIG. 15C, in this embodiment, after the performing of the fourth etching process 290, the upper portion 202pue has top corners 202ta′. The curvature of the top corner 202ta′ is greater than the curvature of the top corner 202ta. In an embodiment, a top part of the upper portion 202pue resembles a semicircle having a convex top surface that curves outward. In an embodiment, the radius of curvature of the top corner of the upper portion 202pue of the silicon pillar 202p is greater than 10 nm such that the top corner is smooth enough to alleviate tip discharge effect. After performing the fourth etching process 290, operations in blocks 108-112 may be then performed to finish the fabrication of the semiconductor structure 200.

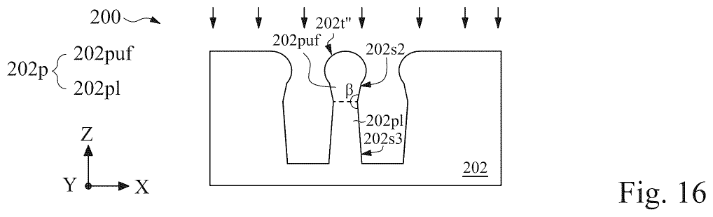

FIG. 16 depicts a fragmentary cross-sectional view of a sixth alternative workpiece, during various stages of operations in the method of FIG. 1, according to various aspects of the present disclosure. In an example process, with reference to FIGS. 4-5, after performing the second etching process 212 to trim the upper portion 202pu of the silicon pillar 202p and after performing the third etching process 213 to selectively remove of the patterned hard mask 204′, the fourth etching process 290 (described with reference to FIGS. 15C) is performed to further trim the substrate 202, including the upper portion 202pu′ of the silicon pillar 202p. The extent at which the substrate 202 is further trimmed is controlled by the duration of the fourth etching process 290. In an embodiment, the performing of the fourth etching process 290 would not substantially etch the lower portion 202pl of the silicon pillar 202p. The upper portion 202pu′ of the silicon pillar 202p after the performing of the fourth etching process 290 may be referred to as the upper portion 202puf. The sidewall 202s2 and a sidewall 202s3 of the lower portion 202pl of the semiconductor pillar 202p forms an obtuse angle β that is greater than 180°. As represented by FIG. 16, in this embodiment, after the performing of the fourth etching process 290, the upper portion 202puf has top corners 202t″. The curvature of the top corners 202t″ is greater than the curvature of the top corners 202t′ (shown in FIG. 4). In an embodiment, a top part of the upper portion 202puf resembles a major arc having a convex top surface that curves outward. In an embodiment, the radius of curvature of the top corner of the upper portion 202puf of the silicon pillar 202p is greater than 10 nm such that the top corner is smooth enough to alleviate tip discharge effect. After performing the fourth etching process 290, operations in blocks 108-112 may be then performed to finish the fabrication of the semiconductor structure 200.

Although not intended to be limiting, one or more embodiments of the present disclosure provide many benefits to semiconductor structures including deep trench capacitors (DTCs) and methods of forming the same. For example, the present disclosure provides methods of solving tip discharge issue at edges or corners of semiconductor pillars disposed between portions of the DTCs formed in trenches. Reducing or even eliminating tip discharge can reduce the possibility of damage to the deep trench capacitors (DTCs) caused by the tip discharge, thereby advantageously improving reliability (e.g., increasing breakdown voltage) of the deep trench capacitors (DTCs) formed adjacent to and over the semiconductor pillars.

The present disclosure provides for many different embodiments. Semiconductor structures and methods of fabrication thereof are disclosed herein. In one exemplary aspect, the present disclosure is directed to a method. The method includes forming a patterned hard mask over a semiconductor substrate, the patterned hard mask exposing a first portion of the semiconductor substrate and covering a second portion of the semiconductor substrate adjacent to the first portion, wherein the second portion may include an upper part in direct contact with the patterned hard mask and a lower part, performing a first etching process to recess the first portion and the lower part of the second portion to form a trench, performing a second etching process to trim corners of the upper part of the second portion, after the performing of the second etching process, selectively removing the patterned hard mask, and forming a capacitor in and over the trench.

In some embodiments, after the performing the second etching process, the corners of the upper part of the second portion may be rounded corners. In some embodiments, etchant of the first etching process may be different than etchant of the second etching process. In some embodiments, the etchant of the first etching process may include a fluorine-containing etchant. In some embodiments, the performing of the second etching process may include implementing argon. In some embodiments, a process pressure of the second etching process may be lower than 20 millitorr. In some embodiments, the performing of the second etching process may also reduce a dimension of the patterned hard mask. In some embodiments, after the performing of the second etching process, the upper part spans a first width and a topmost surface of the upper part spans a second width less than the first width. In some embodiments, the method may also include, after the selectively removing of the patterned hard mask, performing a thermal oxidization process to the semiconductor substrate to form an oxide layer. In some embodiments, the oxide layer has a non-uniform thickness. In some embodiments, the forming of the capacitor may include conformally depositing a first conductive layer, conformally depositing a first dielectric layer on the first conductive layer, patterning the first conductive layer and the first dielectric layer to form a first conductor plate and a first insulation layer, respectively, conformally depositing a second conductive layer, conformally depositing a second dielectric layer on the second conductive layer, and patterning the second conductive layer and the second dielectric layer to form a second conductor plate and a second insulation layer, respectively.

In another exemplary aspect, the present disclosure is directed to a method. The method includes forming a patterned mask over a substrate, performing a first etching process using the patterned mask as an etch mask to etch the substrate to form a trench, wherein a width of the trench is not uniform from bottom to top, performing a second etching process, wherein the performing of the second etching process reduces a width of the patterned mask and trims a portion of the substrate under the patterned mask, selectively removing the patterned mask, and forming a capacitor in and over the trench.

In some embodiments, the second etching process may include a plasma etch. In some embodiments, the performing of the second etching process may include implementing a combination of argon and a fluorine-containing gas. In some embodiments, the first etching process etches the patterned mask at a first rate, the second etching process etches the patterned mask at a second rate higher than the first rate. In some embodiments, the second etching process etches the substrate at a third rate higher than the second rate. In some embodiments, the patterned mask comprises a first mask layer over a second mask layer, the method may also include performing a third etching process to further trim the portion of the substrate under the patterned mask, the selectively removing of the patterned mask comprises selectively removing the first mask layer before the performing of the third etching process and selectively removing the second mask layer after the performing of the third etching process.

In yet another exemplary aspect, the present disclosure is directed to a semiconductor structure. The semiconductor structure includes a capacitor disposed in and over a substrate and comprising a first portion extending into a first region of the substrate, a second portion extending into a second region of the substrate, and a third portion disposed over a third region of the substrate and extending from the first portion to the second portion, where the third region of the substrate may include an upper part having a profile resembling an inverted trapezoid with rounded top corners.

In some embodiments, the semiconductor structure may also include a dielectric layer disposed between the capacitor and the substrate and a passivation structure disposed over the capacitor and in direct contact with the dielectric layer. In some embodiments, the capacitor may include a vertical stack of alternating conductor plates and insulation layers. In some embodiments, a radius of curvature of each of the rounded corners is greater than 10 nm.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a patterned hard mask over a semiconductor substrate, the patterned hard mask exposing a first portion of the semiconductor substrate and covering a second portion of the semiconductor substrate adjacent to the first portion, wherein the second portion comprises an upper part in direct contact with the patterned hard mask and a lower part;
performing a first etching process to recess the first portion and the lower part of the second portion to form a trench;
performing a second etching process to trim corners of the upper part of the second portion;
after the performing of the second etching process, selectively removing the patterned hard mask; and
forming a capacitor in and over the trench.

2. The method of claim 1, wherein, after the performing the second etching process, the corners of the upper part of the second portion are rounded corners.

3. The method of claim 1, wherein etchant of the first etching process is different than etchant of the second etching process.

4. The method of claim 3, wherein the etchant of the first etching process comprises a fluorine-containing etchant.

5. The method of claim 3, wherein the performing of the second etching process comprises implementing argon.

6. The method of claim 1, wherein a process pressure of the second etching process is lower than 20 millitorr.

7. The method of claim 1, wherein the performing of the second etching process further reduces a dimension of the patterned hard mask.

8. The method of claim 1, wherein, after the performing of the second etching process, the upper part spans a first width, and a topmost surface of the upper part spans a second width less than the first width.

9. The method of claim 1, further comprising:
after the selectively removing of the patterned hard mask, performing a thermal oxidization process to the semiconductor substrate to form an oxide layer.

10. The method of claim 9, wherein the oxide layer has a non-uniform thickness.

11. A method, comprising:
forming a patterned mask over a substrate;
performing a first etching process using the patterned mask as an etch mask to etch the substrate to form a trench, wherein a width of the trench is not uniform from bottom to top;
performing a second etching process, wherein the performing of the second etching process reduces a width of the patterned mask and trims a portion of the substrate under the patterned mask;
selectively removing the patterned mask; and
forming a capacitor in and over the trench.

12. The method of claim 11, wherein the second etching process comprises a plasma etch.

13. The method of claim 11, wherein the performing of the second etching process comprises implementing a combination of argon and a fluorine-containing gas.

14. The method of claim 11, wherein the first etching process etches the patterned mask at a first rate, the second etching process etches the patterned mask at a second rate higher than the first rate.

15. The method of claim 14, wherein the second etching process etches the substrate at a third rate higher than the second rate.

16. The method of claim 11, wherein the patterned mask comprises a first mask layer over a second mask layer, the method further comprising:
performing a third etching process to further trim the portion of the substrate under the patterned mask, wherein the selectively removing of the patterned mask comprises selectively removing the first mask layer before the performing of the third etching process and selectively removing the second mask layer after the performing of the third etching process.

17. A semiconductor structure, comprising:
a capacitor disposed in and over a substrate and comprising:
a first portion extending into a first region of the substrate,
a second portion extending into a second region of the substrate, and
a third portion disposed over a third region of the substrate and extending from the first portion to the second portion,
wherein the third region of the substrate comprises an upper part having a profile resembling an inverted trapezoid with rounded top corners.

18. The semiconductor structure of claim 17, further comprising:
a dielectric layer disposed between the capacitor and the substrate; and
a passivation structure disposed over the capacitor and in direct contact with the dielectric layer.

19. The semiconductor structure of claim 17, wherein the capacitor comprises a vertical stack of alternating conductor plates and insulation layers.

20. The semiconductor structure of claim 17, wherein a radius of curvature of each of the rounded corners is greater than 10 nm.
